(19) United States
(12) Patent Application Publication
(10) Pub. No.: US 2026/0165029 A1
(43) Pub. Date: Jun. 11, 2026

(54) METHOD FOR PREPARING A THIN LAYER OF FERROELECTRIC MATERIAL

(71) Applicant: Soitec, BERNIN (FR)

(72) Inventors: Djamel Belhachemi, BERNIN (FR); Raphaël Caulmilone, BERNIN (FR); Isabelle Huyet, BERNIN (FR); Oleg Kononchuk, BERNIN (FR)

(21) Appl. No.: 18/707,745

(22) PCT Filed: Sep. 28, 2022
(86) PCT No.: PCT/FR2022/051837

§ 371 Date: May 6, 2024

(30) Foreign Application Priority Data
Nov. 10, 2021 (FR) FR2111960

(51) Int. Cl. H10N 30/04; H10N 30/073; H10N 30/082; H10N 30/086; H10N 30/853

(52) U.S. Cl. CPC H10N 30/04; H10N 30/073; H10N 30/082; H10N 30/086; H10N 30/8542

(57) ABSTRACT

A method of preparing a thin film of ferroelectric material comprises a step of providing the thin film, the thin film having an exposed free face, and a step of thinning by ion etching, which step is defined by etching parameters. The etching parameters are chosen so that the free face of the thin film has a roughness that does not exceed a threshold value at the end of the thinning step.

### CROSS-REFERENCE TO RELATED APPLICATIONS

This application is a national phase entry under 35 U.S.C. § 371 of International Patent Application PCT/FR2022/051837, filed Sep. 28, 2022, designating the United States of America and published as International Patent Publication WO 2023/084164 A1 on May 19, 2023, which claims the benefit under Article 8 of the Patent Cooperation Treaty of French Patent Application Serial No. FR2111960, filed Nov. 10, 2021.

### TECHNICAL FIELD

The present disclosure relates to a method for preparing a thin film of ferroelectric material. More particularly, it relates to a preparation method making it possible to maintain the monodomain nature of the ferroelectric material in the thin film of the final product. This preparation method is used, for example, in the fields of microelectronics, micromechanics, photonics, etc.

### BACKGROUND

A ferroelectric material is a material that has an electric polarization in the natural state, polarization that may be reversed by applying an external electric field. “Ferroelectric domain” refers to each region in a single piece of the material in which the polarization is uniform (all the dipole moments are aligned parallel to each other in a given direction). A ferroelectric material may therefore be characterized as “monodomain,” in the case where this material is formed by a single region in which the polarization is uniform, or as “multidomain,” in the case where the ferroelectric material comprises a plurality of regions having different polarities.

Various processes are known from the state of the art for forming a thin film of ferroelectric material. It may, for example, be a technique using molecular beam epitaxy, plasma sputtering, laser pulsed deposition, or even the application of SMARTCUT™ technology, whereby a thin film is removed from a solid substrate of ferroelectric material by fracturing on a fragile zone (or embrittlement plane) formed in the solid substrate by implantation of light species.

The present disclosure relates more particularly to the preparation of a ferroelectric thin film obtained by the application of such a method, and of which a specific example embodiment may be found in the document EP3646374B1.

According to this method, and after the step of removing the film, it is often necessary to apply treatments to the film aimed at improving its surface state or its crystalline quality or modifying its thickness. It has been observed, however, that these preparation steps, when they were applied to a ferroelectric thin film transferred onto a silicon support, could lead to the formation of a plurality of ferroelectric domains within the thin film, thus giving it a multidomain nature.

Such a feature makes the film unfit for use, since it affects the performance of the devices that are to be formed on/in the thin film, such as, for example, surface acoustic wave devices (SAW).

Document WO2020200986 discloses that the formation of ferroelectric domains in a surface portion of the film is caused by the existence of hydrogen concentration gradients in the thin film during the application of a thermal treatment. This hydrogen may, in particular, correspond to the light species implanted in the solid substrate in order to form therein the embrittlement zone, making it possible to remove the thin film by splitting along the embrittlement zone. To permanently restore the monodomain nature of the thin film, this document recommends thinning the ferroelectric thin film after the application of such a thermal treatment.

This thinning may be achieved, in particular, by chemical-mechanical polishing of the film, but the removal of a relatively large thickness of materials by polishing tends to deteriorate the uniformity of thickness of this film. By way of example, the removal of a thickness on the order of 400 nm to achieve a target thickness of approximately 700 nm results in the formation of a film having a thickness uniformity (i.e., the difference between the greatest thickness and the least thickness when this thickness measurement is carried out, for example, by reflectometry or ellipsometry, at multiple measurement points over the entire extent of the film) on the order of 100 nm. This variability in thickness is not acceptable, since it does not make it possible to collectively manufacture, from such a film, devices having all the required features.

Alternatives exist to thinning by chemical-mechanical polishing. It is possible, in particular, to envisage thinning the thin ferroelectric film by ion etching, for example, by etching with reactive ions (or RIE etching for “reactive ion etching” according to the expression usually employed). RIE is a type of dry etching that uses a chemically reactive ion plasma to remove surface material from a wafer. The plasma is generated under low pressure by an electromagnetic field. The high-energy plasma ions attack the surface of the film and react therewith to pulverize it, thereby gradually thinning it.

Thus, document US2018261756 proposes to form a thickness of about 2 microns of PZT by CSD deposition to form an amorphous piezoelectric film. This film is exposed to temperature to form a polycrystal. A thickness of 50 nm is then etched, for example, by RIE etching, in order to reduce its roughness and improve its dielectric voltage.

### BRIEF SUMMARY

The present disclosure aims to determine the conditions for applying ion etching to the free face of a thin film of monocrystalline ferroelectric material with a view to thinning it. An object of the present disclosure is to propose a method for preparing a thin film of ferroelectric material partially addressing at least the aforementioned drawbacks. More particularly, an object of the present disclosure is to propose a method for ion etching of a thin film of monocrystalline ferroelectric material, obtained by detachment from a donor substrate at an embrittlement plane, this method preserving or restoring the monodomain nature of the thin film. Another object of the present disclosure is to propose a method for thinning a thin film obtained by detachment at an embrittlement plane of a donor substrate, the thinning method making it possible to form a thin film of monocrystalline ferroelectric material, which is monodomain and has a thickness more uniform than that which may be obtained by a thinning process implementing chemical-mechanical polishing.

With a view to achieving one of these objects, the subject of the present disclosure is a method for preparing a thin film of monocrystalline ferroelectric material, the method comprising the following steps:
a step of providing a thin film, the thin film exposing a first free face;
a step of thinning the thin film by ion etching and defined by etching parameters.

According to the present disclosure, the providing step comprises the assembly of a donor substrate comprising an embrittlement plane with a support substrate and the detachment of the thin film at the level of the embrittlement plane, the thin film having a second face opposite the free face and placed on the support substrate. Furthermore, the etching parameters are chosen so that the free face of the thin film has a roughness that does not exceed a threshold value at the end of the thinning step.

According to other advantageous and non-limiting features of the present disclosure, taken alone or in any technically feasible combination:
the providing step comprises forming the embrittlement plane by hydrogen ion implantation in the donor substrate;
the donor substrate is a block of solid material;
the donor substrate comprises a thick layer of ferroelectric material arranged on a manipulator substrate;
the thinning step is followed by chemical-mechanical touch-polishing of the free face;
the providing step comprises a thermal treatment step exposing the free face of the thin film to a certain gaseous atmosphere;
the thermal treatment is carried out at a temperature between 300° C. and the Curie temperature of the ferroelectric material making up the thin film, and for a period of between 30 minutes and 10 hours;
the thermal treatment is carried out under an oxidizing or neutral gaseous atmosphere;
the method comprises, between the thermal treatment step and the thinning step, a step of smoothing the free face to reduce its surface roughness to a value below the roughness threshold value;
the smoothing step comprises chemical-mechanical touch-polishing of the free face;
the roughness threshold value is between 3 nm and 7 nm.

According to another aspect, the present disclosure relates to a substrate comprising a thin film of monocrystalline and monodomain ferroelectric material disposed on a support, the thin film having a thickness less than or equal to 700 nm and a thickness uniformity less than or equal to 60 nm.

According to other advantageous and non-limiting features of the present disclosure, taken alone or in any technically feasible combination:
the substrate comprises an amorphous interlayer placed between the thin film and the support;
the amorphous interlayer is a silicon oxide, a silicon oxynitride, or a silicon nitride;
the thin film comprises a free face having a roughness of less than 0.5 nm;
the ferroelectric material of the thin film is LiTaO₃ or LiNbO₃;
the ferroelectric material of the thin film has a 42° RY crystalline direction;
the support comprises, on the thin film side, a charge trapping layer.

### BRIEF DESCRIPTION OF THE DRAWINGS

Further features and advantages of the present disclosure will become apparent from the following detailed description of example embodiments of the present disclosure, with reference to the appended figures, in which:

FIGS. 1A-1D show a thin film providing step according to a first embodiment;

FIGS. 2A-2D show a thin film providing step according to a second embodiment; and

FIGS. 3A-3B show a preparation method according to the present disclosure.

### DETAILED DESCRIPTION

For the sake of simplifying the following description, the same reference signs are used for identical elements or for elements performing the same function in the different embodiments of the method disclosed.

The figures are schematic representations, which, for the sake of readability, are not to scale. In particular, the thicknesses of the layers are not to scale with respect to the lateral dimensions of these layers.

The expression “thermal expansion coefficient” used in the remainder of this description in relation to a layer or substrate refers to the expansion coefficient in a direction defined in the principal plane defining this layer or this substrate. If the material is anisotropic, the retained value of the coefficient will be the value with the greatest amplitude. The value of the coefficient is that which is measured at room temperature.

The present disclosure relates to a method for preparing a thin film 3 made of a ferroelectric material transferred from a monocrystalline donor substrate 1 to a support substrate 7 by a transfer technique including implanting light species in the donor substrate 1. Several embodiments of this providing step of a thin film exist.

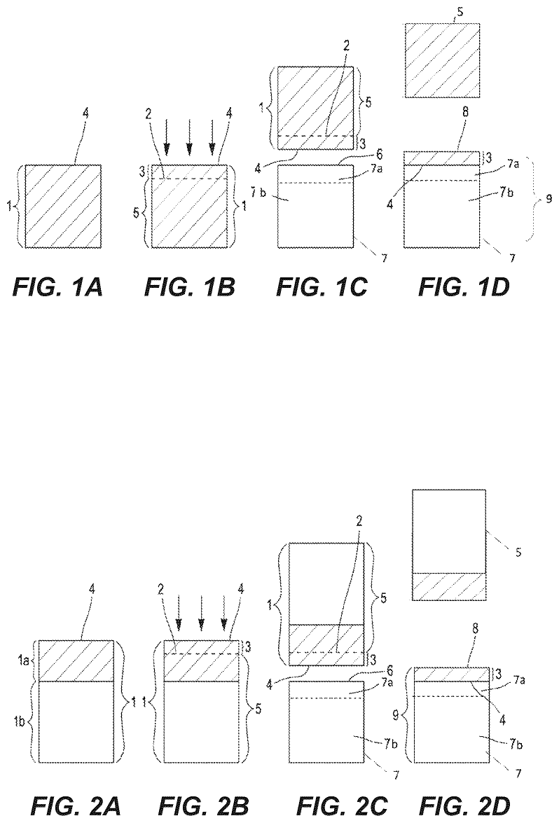

According to a first embodiment, shown in FIGS. 1A to 1D, the donor substrate 1 is composed of a solid, monocrystalline and monodomain block of ferroelectric material, for example, of LiTaO₃, LiNbO₃, LiAlO₃, BaTiO₃, PbZrTiO₃, KnbO₃, BaZrO₃, CaTiO₃, PbTiO₃ or KTaO₃. The donor substrate 1 may assume the form of a circular wafer of standardized size, for example, 150 mm or 200 mm in diameter. However, the present disclosure is by no means limited to these dimensions or to this shape. The donor substrate may have been removed from an ingot of ferroelectric materials, with this removal having been carried out so that the donor substrate 1 has a predetermined crystalline orientation. The orientation is chosen according to the intended application. Thus, it is common practice to choose an orientation of 42° RY, in the case where the intention is to exploit the properties of the thin film to form a SAW filter. However, the present disclosure is in no way limited to a particular crystalline orientation.

Irrespective of the crystalline orientation of the donor substrate 1, the method comprises the introduction into the donor substrate 1 of at least one light atomic species. This introduction may correspond to an implantation, i.e., an ion bombardment of a plane face 4 of the donor substrate 1 by light atomic species such as hydrogen and/or helium ions.

In a manner known per se, and as shown in FIG. 1B, the purpose of the implanted ions is to form an embrittlement plane 2 delimiting a thin film 3 of ferroelectric material to be transferred that is located on the side of the plane face 4 and another part forming the remainder 5 of the donor substrate 1.

The nature, the dose of the implanted atomic species, and the implantation energy are chosen as a function of the thickness of the film that is intended to be transferred and of the physico-chemical properties of the donor substrate. In the case of a donor substrate 1 made from LiTaO₃, it will thus be possible to choose to implant a hydrogen dose of between 1E16 and 5E17 at/cm² with energy that is between 30 and 300 keV to delimit a thin film 3 having a thickness on the order of 200 to 2000 nm.

In a following step, shown in FIG. 1C, the plane face 4 of the donor substrate 1 is assembled with a plane face 6 of a support substrate 7. The support substrate 7 may be the same size and the same shape as those of the donor substrate. For reasons of availability and cost, the support substrate 7 is a monocrystalline or polycrystalline silicon wafer. More generally, however, the support substrate 7 may be formed of any material, for example, silicon, sapphire, or glass, and be any shape.

In a particular embodiment, the support substrate comprises a base substrate 7b, for example, of monocrystalline silicon, on which is arranged a charge trapping layer 7a. The base substrate 7b may have a high resistivity, greater than 1000 ohms.cm or more conventionally, less than 1000 ohms.cm. The charge trapping layer 7a, as is known per se, may be formed from a layer of polycrystalline silicon and have a thickness typically between 500 nm and 10 microns.

Prior to the assembly step, the faces of the substrates to be assembled may be prepared using a cleaning, brushing, drying, or polishing step, or using an activation, for example, by plasma.

The assembly step may involve placing the donor substrate 1 in close contact with the support substrate 7 by molecular adhesion and/or electrostatic bonding. Optionally, to facilitate the assembly of the two substrates 1, 7, in particular, when they are assembled by direct bonding, at least one amorphous interlayer may be formed prior to assembly, either on the plane face 4 of the donor substrate 1, or on the plane face 6 to be assembled of the support substrate 7, or on both. This interlayer is, for example, made of silicon oxide, silicon nitride, silicon oxynitride. It may have a thickness of between a few nanometers and a few microns.

Preference will be given to an interlayer having a low hydrogen concentration or forming a barrier to hydrogen diffusion to follow the teachings of document WO2020200986 and thus avoiding the formation of a multidomain zone at the interface between the thin film and the amorphous interlayer on the side of the second face of the thin film 3. The interlayer may be produced according to the various techniques that are known in the state of the art, such as thermal oxidation or nitridation treatments, chemical depositions (PECVD, LPCVD . . . ), etc.

At the end of this assembly step, an assembly is obtained comprising the two associated substrates, the plane face 6 of the support substrate 7 adhering to the plane face 4 of the donor substrate 1.

The assembly is then treated to detach the thin film 3 of ferroelectric material from the donor substrate 1, for example, by cleavage at the embrittlement plane 2.

This detachment step may thus comprise applying a thermal treatment to the assembly within a temperature range on the order of 80° C. to 300° to allow the thin film 3 to be transferred onto the support substrate 7. In place of or in addition to the thermal treatment, this step may comprise the application of a blade or a jet of gaseous or liquid fluid at the embrittlement plane 2.

Following this detachment step, the structure 9 shown in FIG. 1D is obtained. This structure 9 comprises the thin film 3 of monocrystalline ferroelectric material comprising a first free face 8 and a plane face 4 arranged on the support substrate 7.

FIGS. 2A to 2D show a second embodiment, particularly suitable for producing a heterogeneous structure 9, in which the thin film 3 has a thermal expansion coefficient that is very different from that of the support substrate 7, for example, having a difference of more than 10%. This second embodiment differs from the first embodiment mainly by the nature of the donor substrate 1. For the sake of brevity, only the elements of this second embodiment differing from the first are therefore presented here, all the other features of the first embodiment thus being able to be envisaged.

With reference to FIG. 2A, the donor substrate 1 in this case is composed of a thick layer of ferroelectric material 1a, having the same properties as those described for the solid block of ferroelectric materials in relation to the first embodiment, and of a manipulator substrate 1b.

The manipulator substrate 1b is advantageously formed of a material (or a plurality of materials) providing it with a thermal expansion coefficient close to that making up the support substrate 7. “Close” means that the difference in the thermal expansion coefficient of the manipulator substrate 1b and that of the support is less, as an absolute value, than the difference in the thermal expansion of the solid block of ferroelectric material and that of the support substrate 7.

Preferably, the manipulator substrate 1b and the support substrate have an identical thermal expansion coefficient. During the assembly of the donor substrate 1 and the support substrate 7, a structure is formed that is suitable to withstand a thermal treatment at a relatively high temperature. For the sake of simplicity of implementation, this may be obtained by choosing the manipulator substrate 1b so that it is formed of the same material as that of the support substrate 7.

To form the donor substrate 1 of this embodiment, a solid block of ferroelectric material is first assembled with the manipulator substrate 1b, for example, according to a bonding technique by molecular adhesion as described above or with the help of an adhesive layer. Then, the film of ferroelectric material 1a is formed by thinning, for example, by grinding and/or chemical-mechanical polishing and/or etching. Before assembly, provision may be made for the formation of an adhesion layer (for example, by deposition of silicon oxide and/or silicon nitride, of an adhesive layer, for example, a polymer) on one and/or the other of the faces that are brought into contact. The assembly may include the application of low-temperature thermal treatment (for example, between 50° and 300° C., typically 100° C.) allowing sufficient strengthening of the bonding energy to allow the next step of thinning.

The manipulator substrate 1b is chosen to have a thickness that is substantially equivalent to that of the support substrate 7. The thinning step is carried out so that the thickness of the ferroelectric material 1a is small enough for the stresses generated during the thermal treatments applied in the rest of the process to have a lower intensity. At the same time, this thickness is large enough to be able to remove the thin film 3, or a plurality of such films. This thickness may, for example, be between 5 and 400 microns.

The following steps of the method of this second embodiment are equivalent to those of the steps described in the first embodiment. Light species are implanted within the ferroelectric material 1a to generate an embrittlement plane 2, which marks the separation of the thin film 3 from the remainder 5 of the donor substrate 1, as shown in FIG. 2B. This step is followed by the step of assembling the donor substrate 1 on the support substrate 7, as shown in FIG. 2C. The thin film 3 is then detached from the remainder 5 of the donor substrate 1 in order to obtain the structure 9 shown in FIG. 2D.

This embodiment is advantageous in that the assembly formed from the donor substrate 1 and the support substrate 7 may be exposed to a temperature that is much higher than that applied in the first embodiment, without any risk of uncontrolled fracturing of one of the substrates or delamination of the donor substrate 1 of the thin film 3. The balanced structure, in terms of the thermal expansion coefficient of this assembly, thus makes it possible to facilitate the step of detaching the thin film 3 by exposing the assembly to a relatively high temperature, for example, between 100° C. and 500° C.

Irrespective of the embodiment chosen, and as specified in the introduction to the present disclosure, stages of finishing the thin film 3 are then necessary to improve its crystalline and surface quality, and provide a thin film 3, the thickness of which matches, or approaches, a target thickness. These finishing steps aim, in particular, to eliminate a work-hardened and rough surface layer, resulting from the cleavage and detachment of the thin film 3 from the rest of the donor substrate.

As explained in document WO2020200986, a thermal treatment step is first applied to the transferred thin film 3. This thermal treatment makes it possible to cure the crystalline defects present in the thin film 3, or even to reduce the roughness of the free face of the thin film. Moreover, it helps to consolidate the bond between the thin film 3 and the support substrate 7. The thermal treatment brings the structure to a temperature between 300° C. and the Curie temperature of the ferroelectric material for a period of between 30 minutes and 10 hours. This thermal treatment is preferably carried out by exposing the free face of the thin film 3 to an oxidizing or neutral gaseous atmosphere, i.e., without covering this face of the thin film with a protective layer.

To avoid any ambiguity, it is emphasized that the finishing thermal treatment step of the thin film 3 is distinct from the fracture thermal treatment applied to the assembled structure.

A method in accordance with the present disclosure also comprises, after the finishing thermal treatment, a step of thinning the thin film 3. This step aims, in particular, to eliminate the multidomain surface layer, which may have been created during the previous thermal treatment step. It also aims to provide a thin film 3, the thickness of which corresponds to a target thickness, as mentioned previously. This thinning may, in a general way, involve polishing of the first free face 8 of the thin film 3, for example, by mechanical, chemical-mechanical thinning techniques. This thinning may result in removing a thickness of between 100 nm and 1 micron, depending on the thickness of the transferred layer, the target thickness of the thin film 3, the thickness of the multidomain, and/or work-hardened layer present superficially from the finishing thermal treatment. However, as was presented in the introduction to the present disclosure, such an approach of thinning by chemical-mechanical polishing tends to degrade the characteristic of uniformity of the thin film 3, which is not acceptable. Additional experiments carried out have thus shown that this uniformity degrades by about 25 nm for a removal of 100 nm.

In the search for an alternative solution to thinning by polishing, the following experiments aimed at implementing this step of thinning by ion etching has been carried out.

An experimental sample consisted of a monocrystalline thin film of lithium tantalate transferred onto a silicon substrate (in accordance with the method that has just been disclosed and including the finishing thermal treatment), the thin film however not having undergone any thinning stage. The preparation method applied to this thin film therefore consisted only of the thermal treatment step. The thin film therefore had a multidomain surface thickness. It had a thickness of 680 nm and a roughness on the order of 10 nm RMS.

On this sample, a first RIE P1-type ion etching process and a second RIE P2-type ion etching process were applied, respectively, each based on a reactive gas of CHF₃. As recalled in the introduction to the present disclosure, an RIE etching process consists of exposing the surface to be treated (here the free face 8 of the thin film 3) to a reactive ion plasma. This plasma leads to surface etching of the material comprising the free face of the thin film.

The effect of an ion etching, in particular, of the RIE type, on the roughness of the film, is dependent on the etching parameters, and, in particular, on the power of the radio frequency field formed to create the plasma of reactive ions, on the flow rate of the reactive gas, on the temperature of the thin film (which may be controlled by controlling the temperature of the support on which the substrate rests), and on the pressure prevailing in the treatment chamber of the RIE equipment.

The first RIE P1 process applied to the sample presented etching parameters tending to increase the roughness of the thin film, in particular, by choosing a flow rate of reactive gas introduced into the chamber of 65 sccm (for “Standard Cubic Centimeter per Minute”), i.e., 1.08 10\hat{ }−6 m\hat{ }3/s for standard conditions. The process was applied to the sample to reduce the thickness of the thin film by 200 nm and therefore to achieve a thickness of 480 nm.

The second RIE P2 process applied to the sample presented etching parameters tending to reduce the roughness of the thin film, in particular, by choosing a flow rate of reactive gas introduced into the chamber of 20 sccm, i.e., 0.3 10\hat{ }−6 m\hat{ }3/s under standard conditions. The process was applied to the sample to reduce the thickness of the thin film by 200 nm and therefore lead to a thickness of 480 nm.

The following table presents the results obtained at the end of the experiments carried out. The roughnesses are expressed in RMS quantities measured on a field of 5×5 μm by measurement by atomic force.

| | Characteristic of the thin film after the thinning step |
|---|---|
| P1 | Multidomain |
| | Roughness: 17 nm |
| | Uniformity: 15.3 nm |
| P2 | Monodomain |
| | Roughness: 2.9 nm |
| | Uniformity: 9.9 nm |

It should be noted that the application of the first process P1 (the etching parameters of which tend to increase the roughness of the thin film) leads to obtaining a thinned film with high roughness. Moreover, and contrary to what was expected, the monodomain nature of this thin film 3 has not been restored.

On the contrary, the application of the second process P2 (the etching parameters of which tend to reduce the roughness of the thin film) leads not only to obtaining a thinned film, the roughness of which is much less, but which also makes it possible to restore the monodomain nature of the thin film 3.

It should be noted in both cases that the uniformity of the sample, not having undergone thinning treatment by polishing, is of good quality.

According to a possible interpretation of these results, which in no way limits the performance of the preparation method of the present disclosure, it would seem that the ions of the plasma interact with the piezoelectric material present in the peaks of roughness when the roughness is excessive, for modifying its polarization properties, which results in creating or maintaining superficially a multidomain thickness.

To guard against this phenomenon, it therefore appears necessary to choose the etching parameters to reduce the roughness of the thin film below a threshold value from which this modification of the polarization properties is triggered.

The greater the initial roughness of the thin film, i.e., the roughness of the thin film just before the application of the thinning step, and, in particular, when it exceeds the roughness threshold value, the more the etching parameters must be controlled in order to reduce and/or not exceed the roughness threshold value during and at the end of this step. Conversely, the lower the initial roughness, and, in particular, when it is lower than the roughness threshold value, the more the etching parameters may be chosen freely, without however leading to exceeding the roughness threshold value at the end of the thinning step. In this way, the method is able to provide a monodomain thin film, the uniformity of which is much better than that of a film thinned by chemical-mechanical polishing.

Depending on the nature of the ferroelectric material constituting the thin film, the roughness threshold value may be between 3 nm and 7 nm, for example, 5 nm or 6 nm.

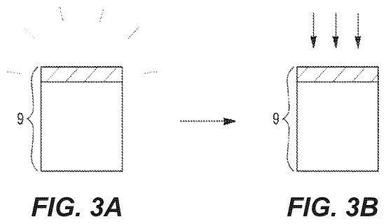

The present disclosure therefore takes advantage of these results to propose a method for preparing the thin film 3, shown schematically in FIG. 3.

The preparation method therefore comprises a providing step of the monocrystalline thin film 3 leading to exposing the first free face 8 of this film, as has been explained previously, for example, according to one or another of the method represented in FIGS. 1A-1D and 2A-2D. This providing step also comprises the application of the finishing thermal treatment step aimed, in particular, at evacuating the hydrogen present in the thin film and leading to the formation of a multidomain surface thickness (FIG. 3A). At the end of this step, the thin film has a determined roughness, typically on the order of 10 nm RMS measured over a field of 5×5 microns by atomic force measurement (AFM). It has a relatively thick thickness on the order of 1000 nm or more.

After this providing step, a preparation method in accordance with the present disclosure comprises a thinning step aimed at providing a chosen layer of thickness, typically on the order of 700 nm or less, i.e., monocrystalline and monodomain.

Very generally, and as shown in FIG. 3B, this thinning step is carried out by ion etching, i.e., exposing the free face 8 of the thin film to ions, advantageously reactive ions. These may, in particular, be ions of argon, of CHF₃, or any other ions capable of reacting chemically with the material making up the piezoelectric thin film. Depending on the thickness of the thin film 3 provided and the target thickness, the thinning step may result in eliminating a thickness on the order of 50 nm to 900 nm, and typically eliminating a thickness greater than 100 nm, for example, between 100 nm and 400 nm. In all cases, the uniformity of the film is much less degraded than when the film is thinned by chemical-mechanical polishing; this thickness uniformity may be less than 60 nm as measured by reflectometry or ellipsometry or even less than 30 nm and even reach 20 nm or less.

To achieve this, and according to the present disclosure, the etching parameters are chosen so that the free face 8 of the thin film 3 has a roughness that does not exceed a threshold value at the end of the thinning step. It is noted that in view of the relatively large thickness to be eliminated, it would have been more natural to choose the etching parameters so that they favor the speed of removal rather than the roughness.

As specified above, the “roughening” effect of the thinning step by ion etching may be reduced by reducing at least one of the following etching parameters: the flow of reactive gases, the power of the radio field frequency formed to create the reactive ion plasma, the temperature of the thin film 3, and the pressure prevailing in the processing chamber of the etching equipment.

The person skilled in the art may very simply adjust these parameters during a series of routine experiments to determine, for a given material and for an initial surface state of the thin film 3, which combination of parameters leads to etching while avoiding exceeding the roughness threshold value.

If the providing step is not sufficiently mastered and this roughness varies from the provision of one thin film to another, the preparation method may provide between the providing step and the thinning step, a step of measuring the roughness of the thin film in order to adjust, layer by layer, the etching parameters of the RIE etching process to the measured roughness.

According to a particularly advantageous embodiment, the preparation method of the present disclosure comprises, between the finishing thermal treatment step and the thinning step, a step of smoothing the free face 8 to reduce its surface roughness at a relatively low initial value, for example, less than 1 nm RMS.

For example, the smoothing step comprises chemical-mechanical touch-polishing of the free face 8. This polishing aims to reduce the roughness of the thin film, without noticeably thinning this film. This very superficial smoothing step does not affect the uniformity of the film.

The roughness of the free face 8 of the thin film 3 being reduced, the etching parameters may be chosen more freely than in the absence of this smoothing step, by reducing the risk of exceeding the roughness threshold value at the end of the thinning step, and therefore by restoring the monodomain nature of the thin film.

Whether this preliminary smoothing step is implemented or not, the method for preparing the thin film may be followed, after the thinning step, by chemical-mechanical touch-polishing of the free face. This step makes it possible to prepare the free face 8 so that it has in the end (if this has not been obtained at the end of the thinning step) a low roughness, for example, less than 0.5 nm RMS 5×5 μm by atomic force measurement (AFM) without affecting the uniformity of this film.

Naturally, the present disclosure is not limited to the embodiments described, and it is possible to add variant embodiments without departing from the scope of the invention as defined by the claims.

1. A method of preparing a thin film of monocrystalline ferroelectric material, the method comprising the following steps:
a step of providing the thin film, the thin film having an exposed first free face; and
a step of thinning the thin film by ion etching and defined by etching parameters;
wherein the step of providing comprises assembly of a donor substrate comprising an embrittlement plane with a support substrate and a detachment of the thin film at a level of the embrittlement plane, the thin film having a second face opposite the first free face and placed on the support substrate, and wherein the etching parameters are chosen so that the first free face of the thin film has a roughness that does not exceed a threshold value at the end of the thinning step.

2. The method of claim 1, wherein the step of providing further comprises forming the embrittlement plane by implanting hydrogen ions in the donor substrate.

3. The method of claim 2, wherein the thinning step is followed by chemical-mechanical touch-polishing of the free face.

4. The method claim 3, wherein the step of providing further comprises thermally treating the thin film while exposing the free face of the thin film to a gaseous atmosphere.

5. The method of claim 4, wherein the thermally treating comprises exposing the thin film to a temperature between 300° C. and a Curie temperature of the ferroelectric material, and for a period of between 30 minutes and 10 hours.

6. The method of claim 5, wherein the thermally treating is carried out under an oxidizing or neutral gaseous atmosphere.

7. The method of claim 6, further comprising, between the thermally treating and the thinning step, smoothing the free face to reduce a surface roughness of the free face to a value lower than the roughness threshold value.

8. The method of claim 7, wherein the smoothing step comprises chemical-mechanical touch-polishing of the free face.

9. The method of claim 1, wherein the roughness threshold value is between 3 nm and 7 nm.

10. A substrate comprising a thin film of monocrystalline and monodomain ferroelectric material arranged on a support, the thin film having a thickness less than or equal to 700 nm and a thickness uniformity less than or equal to 60 nm.

11. The substrate of claim 10, further comprising an amorphous interlayer between the thin film and the support.

12. The substrate of claim 11, wherein the amorphous interlayer comprises silicon oxide, silicon oxynitride, or silicon nitride.

13. The substrate of claim 10, wherein the thin film comprises a free face having a roughness of less than 0.5 nm.

14. The substrate of claim 10, wherein the ferroelectric material of the thin film is LiTaO₃ or LiNbO₃.

15. The substrate of claim 10, wherein the support comprises, on a side of the support adjacent of the thin film (3), a charge trapping layer.

16. The method of claim 1, wherein the thinning step is followed by chemical-mechanical touch-polishing of the free face.

17. The method of claim 1, wherein the step of providing further comprises thermally treating the thin film while exposing the free face of the thin film to a gaseous atmosphere.

18. The method of claim 17, wherein the thermally treating is carried out under an oxidizing or neutral gaseous atmosphere.

19. The method of claim 17, further comprising, between the thermally treating and the thinning step, smoothing the free face to reduce a surface roughness of the free face to a value lower than the roughness threshold value.

20. The method of claim 19, wherein the smoothing step comprises chemical-mechanical touch-polishing of the free face.

21. The method of claim 1, wherein the thermally treating comprises exposing the thin film to a temperature between 300° C. and a Curie temperature of the ferroelectric material, and for a period of between 30 minutes and 10 hours.
